(19) United States
(12) Patent Application Publication
(10) Pub. No.: US 2024/0416981 A1
(43) Pub. Date: Dec. 19, 2024

(54) SYSTEMS AND METHODS FOR VERIFYING TRAIN CONTROLLERS

(71) Applicant: CARNEGIE MELLON UNIVERSITY, Pittsburgh, PA (US)

(72) Inventors: Andre PLATZER, Pittsburgh, PA (US); Stefan MITSCH, Pittsburgh, PA (US); Aditi KABRA, Pittsburgh, PA (US)

(21) Appl. No.: 18/024,335

(22) PCT Filed: Nov. 2, 2022
(86) PCT No.: PCT/US2022/048651

§ 371 Date: Mar. 2, 2023

Related U.S. Application Data
(60) Provisional application No. 63/290,860, filed on Dec. 17, 2021.
(60) Provisional application No. 63/276,225, filed on Nov. 5, 2021.

(51) Int. Cl. B61L 27/60; G06F 11/34; G06F 30/20

(52) U.S. Cl. CPC B61L 27/60; G06F 11/3447; G06F 30/20

(57) ABSTRACT

Disclosed herein is a system and method for formally verifying the safety of the Federal Railroad Administration freight train kinematics model with all its relevant forces and parameters, including track slope and curvature, airbrake propagation, and resistive forces as computed by the Davis equation.

### RELATED APPLICATIONS

This application is a national stage application under 35 USC 371 of PCT Application PCT/US2022/048651 filed Nov. 2, 2022 which claims the benefit of U.S. Provisional Patent Applications Nos. 63/276,225, filed Nov. 5, 2021 and 63/290,860, filed Dec. 17, 2021, the contents of which are incorporated herein in their entireties.

### GOVERNMENT INTEREST

This invention was made with United States Government support under contract 693JJ620C000025 awarded by the Federal Railroad Administration Office of Research, Development and Technology. The U.S. Government has certain rights in the invention.

### BACKGROUND

Embedded software for many complex cyber-physical systems, for example, trains, planes, and self-driving cars is safety critical. Errors can have disastrous consequences. To ensure the safety of controllers, formal verification with computer-checked, repeatable mathematical proofs presents a particularly trustworthy method for controller design.

Automated train control improves railroad operation by safeguarding the motion of trains while increasing efficiency by enabling motion within a safe envelope. Train controllers decide when to slow trains down to avoid collisions with other trains on the track, stay inside movement authorities, and navigate slopes, curves and tunnels safely. These systems must base their decisions on detailed motion models to guarantee the absence of overshoot of the movement authority (safety) and limit undershoot (efficiency). Train controllers decide when to enforce braking to prevent movement authority violation and collisions. They must account for all the competing influences that govern train motion. Uphill slopes, for example, decrease velocity, which decreases resistance, which permits a more rapid increase in velocity, slope and curve effect, all while the train's brake force builds gradually until saturation as air pressure propagates along brake pipes. These complex interactions make it hard to design a safe and efficient train controller, and even harder to ensure it is always safe.

Train controllers are assessed relative to a (changing) destination stopping point-called end of movement authority. An overshoot of the end of movement authority is a safety violation, because that risks collision with other trains. The efficiency of the train controller is measured in terms of end of movement authority undershoot.

Existing studies of formally verified train motion do not account for at least two effects amongst track grade, track curvature, resistance, and air brake propagation time, rendering their results inapplicable to most real-world scenarios. The kinematics of a train can be described by a kinematics model. For example, the Federal Railroad Administration has developed such a model, referred to here as the FRA model.

Verification against the full dynamics of the FRA model, in which these effects interact subtly with each other is a challenge. Verification of the FRA model would be significant, because these parameters influence the motion of the train in safety-critical and/or performance-critical ways. Neglecting track slope profile and the gradual propagation of air pressure braking, in particular, can render otherwise verifiably safe train controllers unsafe, since their influence may diminish the train's ability to decelerate, causing collisions.

### SUMMARY OF THE INVENTION

The embodiments described herein use formal verification as a tool to design and verify a train controller, which is a practically important, representative problem with challenges common in other safety-critical embedded systems: complex dynamics with transcendental arithmetic, competing forces with subtle interaction, and effects whose exact magnitude is unknown at proof time.

Before verifying the safety of a controller, the controller must first be designed. Controllers balance efficiency with provable safety. Conservative controllers are mathematically more simplistic, and easier to design and verify, but make railway operations inefficient, but violate performance objectives. A conservative safe controller is first described, and then iteratively made more efficient through the exploitation of characteristics of the physical train dynamics for better but safe control.

The absence of end of movement authority overshoot is proven when using the controller on the FRA model by verification and efficiency is demonstrated by simulation.

To keep the proofs as general and widely applicable as possible, nondeterministic controllers and a paradigm of mathematical abstraction are leveraged. Each controller is intentionally built to be set-valued such that all of its control choices are simultaneously proved safe under all circumstances in the FRA model. The safety of these controllers implies the safety of all their specializations, giving railroads significant freedom in how to adapt the verified controllers for their purposes.

Controller verification follows a two stage process. First, mathematical models of abstract train control motion are proven. Second, proofs of the actual physical models of train control are obtained by uniform substitution to replace the abstract function symbols of the mathematical models with physical terms specific to the FRA model or even specific railroads.

Crucially, the disclosed embodiments use three different types of models: (i) the high-fidelity physics model describing the kinematic motion of trains along the track; (ii) the generalized mathematical abstractions of the physics model disclosed herein; and (iii) simplified but computable approximations of motion models disclosed herein (e.g., Eqs. (4), (5), (12) etc.) and used by the respective train controllers.

The verification provided by the disclosed embodiments proves that the safety of (i) derives from the safety of (ii) and that all control decisions following (iii) are safe in (ii). The proof is written in differential dynamic logic and performed using a hybrid systems theorem prover.

It should be noted that the embodiments are explained in the context of the FRA model, but it is to be understood that the techniques could be applied to any train kinematics model.

### BRIEF DESCRIPTION OF THE DRAWINGS

FIG. 1 is a block diagram showing the relationship between different train models.

FIG. 2 is a listing of the mathematical model (referred to herein as “Model 1”) for train control expressed as a hybrid program of the train's stopping distance.

FIG. 3 is a listing of the mathematical model (referred to herein as “Model 2”) expressed as a hybrid program of the train dynamics.

FIG. 4 is a listing of the mathematical model (referred to herein as “Model 3”) expressed as a hybrid program of the train dynamics split in to three evolution domains.

FIG. 5 is a listing of the mathematical model (referred to herein as “Model 4”) of a train controller and train dynamics. expressed in Taylor polynomials.

FIG. 6 is a listing of the mathematical model (referred to herein as “Model 5”) of a train controller in the kinematic motion model.

FIG. 7 is a graph showing the base enforcement algorithm showing an undershoot.

FIG. 8 is a graph the base enforcement algorithm with offsets showing an overshoot.

FIG. 9 is a graph showing an optimized verified controller (Model 5) that limits undershoot.

FIG. 10 is a graph showing the base enforcement algorithm showing an undershoot for an underpowered train on a crest from 3% uphill to −3% downhill.

FIG. 11 is a graph the base enforcement algorithm without offsets showing an overshoot.

FIG. 13 is a graph showing an optimized verified controller (Model 5) that limits undershoot.

### DETAILED DESCRIPTION

The embodiments described herein utilize formal verification using differential dynamic logic (DDL) as a tool to design and verify a train controller. This is a practically important, representative problem with challenges common in other safety-critical embedded systems: complex dynamics with transcendental arithmetic, competing forces with subtle interaction, and effects whose exact magnitude is unknown at proof time.

The disclosed embodiments provide a novel, formal verification of the safety of the Federal Railroad Administration freight train kinematics model with all its relevant forces and parameters, including track slope and curvature, air brake propagation, and

resistive forces as computed by the Davis equation. Due to the significant competing influence of these parameters on train stopping distances, even designing train controllers is a nontrivial control challenge, which is solved using formal verification.

For increased generality at reduced verification effort, symbolic mathematical generalizations of the train control models are verified and efficient uniform substitutions are subsequently applied to obtain verification results for physical train control models.

Differential Dynamic Logic—DDL is a logic with a deductive proof system for hybrid systems. DDL extends first-order logic with the notion of hybrid programs. A hybrid program runs according to a binary relation between states, mapping start states to end states that a program could reach. The program constructs include assignment, for example, x:=e₁ which instantaneously assigns expression e₁ to variable x. In the special case of nondeterministic assignment, x:=*, the transition relation accounts for any possible real value being assigned to x.

The test operator, as in ?F, aborts the current run if formula F is false. The continuous evolution operator, {x′=f(x)&Q} follows the ordinary differential equation (ODE) x′=f(x) for some nondeterministic amount of time, with evolution domain constraint Q being true throughout the evolution. Sequential composition α; β, runs program α followed by program β, for example, the discrete train controller

followed by the train's ODE β. The nondeterministic choice operator α∪β runs either program α or β, for example, to either accelerate the train with α or brake with β. The loop operator α* runs hybrid program α any non-deterministically chosen n≥0 times. It is important for running a train control loop indefinitely. To express safety properties about hybrid programs, the box modality [α] F is used, which is true in any state from which all runs of hybrid program end in states in which the formula F is true.

For proofs of DDL formulas, DDL inference rules are used. The rules most relevant to the disclosed embodiments are loop (loop), differential invariant (dI), and differential cut (dC).

$$( loop ) \frac{\begin{matrix}Γ ⊢ J & J ⊢ [ α ] J & J ⊢ P\end{matrix}}{Γ ⊢ [ {α}^{*} ] P}$$

$$( dI ) \frac{\begin{matrix}Γ ⊢ {e}_{1} \leq {e}_{2} & Q ⊢ [ {x}^{′} := f ( x ) ] {e}_{1}^{′} \leq {e}_{2}^{′}\end{matrix}}{Γ ⊢ [ {x}^{′} = f ( x ) \& Q ] {e}_{1} \leq {e}_{2}}$$

$$( dC ) \frac{\begin{matrix}Γ ⊢ [ {x}^{′} = f ( x ) \& Q ⋀ C ] P & Γ ⊢ [ {x}^{′} = f ( x ) \& Q ] C\end{matrix}}{Γ ⊢ [ {x}^{′} = f ( x ) \& Q ] P}$$

The loop rule uses an invariant/that holds initially, inductively after each step, and implies the post condition that is to be proven. A differential invariant preserves properties along the flow of a differential equation: if e₁≤e₂ initially and e₁ grows slower than e₂, so e′₁≤e′₂ (where e′₁ and e′₂ are evaluated after substituting in the assignment x′: =f(x) from the differential equation), then it remains true that e₁≤e₂. The idea behind a differential cut is that if formula C holds true at the end of every possible run of differential equation x′:=f(x), then C must hold true throughout its evolution. Differential cuts can be used to accumulate knowledge about a differential equation.

FRA Model of Train Kinematics—The FRA model, provides the forces acting on a train and is expressed in Eq. (1). After the net force on the train has been identified, Newton's second law, using train mass, determines the acceleration that the train experiences, which in turn determines change in velocity and change in position for train control design. The forces are

$$\sum F = - {F}_{G} - {F}_{C} - {F}_{B} + {F}_{L} - {F}_{R} = {m}_{T} a \qquad ( 1 )$$

where:
F_{G} denotes force due to track grade;
F_{C} is resistance due to track curvature;
F_{B} is the braking force;
F_{L} is the force from the locomotive engine (tractive effort)
F_{R} is resistive forces; and
m_{T} is the train mass.

Newton's second law, ΣF=m_{T}a determines train acceleration a. Resistive force F_{R} follows the modified Davis equation:

$${F}_{R} = {A}_{R} w + {B}_{R} n + {C}_{R} w v + {D}_{R} {v}^{2}$$

where A_{R}, B_{R}, C_{R}, D_{R} are experimentally determined positive constants, the numerical value of which, given a choice of units, can be found in other sources. Further, n is the number of axles, and w is the weight of the train.

Grade and curve forces depend on the train position p on the track. Grade force is proportional to train weight w and average track grade grade(p) underneath the train:

$${F}_{G} = {A}_{G} w \cdot grade ( p )$$

Similarly, curve force is a function of average track curvature curve(p) along the train and train weight w:

$${F}_{C} = {A}_{C} w \cdot curve ( p )$$

where A_{C} and A_{G} are positive multiplicative constants.

Braking force can be modeled as the minimum of two linear functions to capture the effect of air pressure brake force buildup and stabilization.

$${F}_{B} = min ( {F}_{B 0} + {f}_{p} t , {F}_{B max} )$$

where:
F_{B0} is the force acting immediately on brake application;
fₚ is the slope with which brake force increases;
t is the elapsed time; and
F_{Bmax} is the force after air pressure in the air pressure brakes saturates.

Brake enforcement and train protection algorithms approximate a solution to a differential equation derived from Eq. (1) to estimate the velocity and position of the train at future times.

Mathematical Model Abstraction—To maximize generality of the embedded software design, minimize verification effort, and simplify future proof maintenance, a mathematical abstraction of the FRA model is disclosed. Concrete verified controllers and their safety proofs for the fully expanded model can be obtained automatically from the verified abstract model by uniform substitution.

The abstract train kinematic model in Eq. (2) below is an ODE in time. The rate of change of position is velocity, and the rate of change of velocity is acceleration. The variables and constants involved, along with their signs, when relevant, are (i) train position p; (ii) velocity v; (iii) velocity and position-independent component of acceleration aₗ ranging from immediate braking ability −bₘₐₓ<0 to maximum train engine acceleration aₘₐₓ>0; (iv) acceleration due to air brakes aₐ in range a_{bmax}<0 to 0; (v) rate of change m_{b} of air brake acceleration, which is mₚ<0 when the brakes are ramping up and 0 otherwise; (vi) map as from position to acceleration due to grade; (vii) map a_{c} from position to acceleration due to curvature; and (viii) velocity-dependent resistance aᵣ. In the chosen sign convention, resistive acceleration is negative.

$${p}^{′} = v , {v}^{′} = {a}_{l} + {a}_{a} + {a}_{s} ( p ) + {a}_{r} ( v ) + {a}_{c} ( p ) , {a}_{b}^{′} = {m}_{b} \qquad ( 2 )$$

with:
aₗ∈[−bₘₐₓ,aₘₐₓ];
aₐ=max(a_{b},a_{bmax}); and
m_{b}∈{0,mₚ}.

The resistance is given by the Davis equation:

$${a}_{r} ( v ) = - \frac{{C}_{R} w v + {D}_{R} {v}^{2}}{{m}_{T}}$$

which has the shape aᵣ=a₁v+a₂v² when a₁=−Cᵣg with gravity g summarizes the linear coefficient of velocity, and

$${a}_{2} = - \frac{{D}_{R}}{{m}_{T}}$$

summarizes the quadratic coefficient. Grade and curvature are represented by unspecified but bounded functions aₛ and a_{c} that map train positions to a numeric value for acceleration due to slope and average curvature, respectively. The quantity aₗ summarizes locomotive tractive effort (aₗ>0) and train deceleration (aₗ<0) as commanded by the train controller, with adjustment for the velocity-independent resistance.

The proven abstract kinematic train model is then instantiated by uniform substitution of DDL to obtain proofs for specific physical kinematic train models such as the FRA model. Similarly, proofs for specific train configurations result from substituting values for coefficients, or even for a specific train state when additionally substituting speed and position.

### Model Structure

A conservative train controller is first developed in DDL based on the abstract train kinematic model given by Eq. (2). The challenge of representing track grade and curve, which are unknown at proof time, are addressed using unspecified maps. To reason about them, the maps are bounded with assumptions quantifying over all arguments. The solution of the disclosed embodiments permits the capture of the full Eq. (2) without conservatively neglecting aₛ(p) and a_{c}(p) when reasoning about it during verification. It generalizes to other embedded software that must reason about unspecified, bounded functions, such aₛ noise or potential fields (e.g., electro-magnetic or gravitational effect).

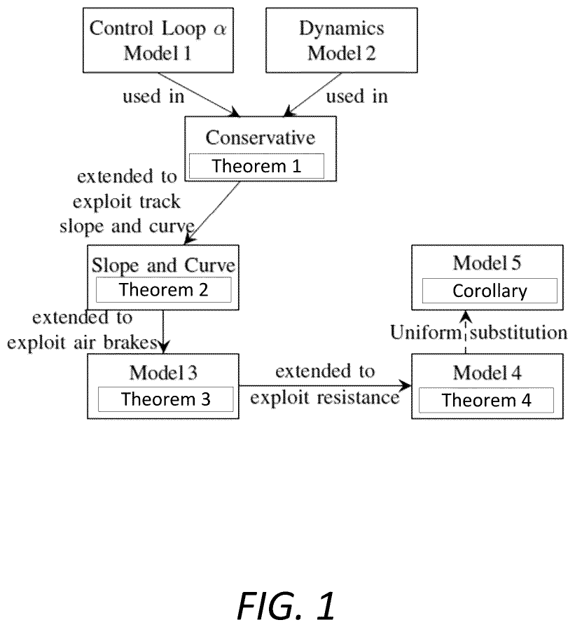

The conservative controller is then proven to be safe. Relative to Eq. (2), the controller will provably never permit the train's position to exceed the end of movement authority e, although it might be inefficient, braking unnecessarily early. By revising modular components and functions to be more arithmetically sophisticated in provable safety can be retained and the controller made more efficient. FIG. 1 shows the relationship between the resulting controller models.

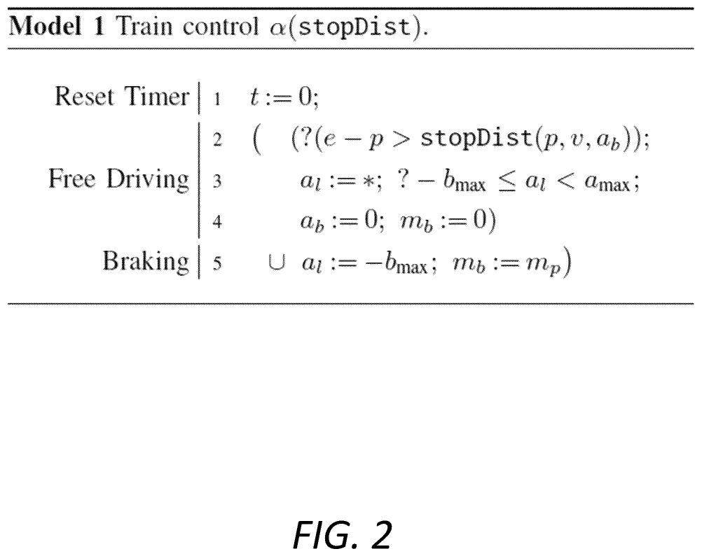

Model Description—The train controller consists of a time control loop. The control has a latency of time T>0. The controller has to wait at most this long before being able to change the throttle position. In practice, reaction time (latency) T is typically on the order of 1 second, but train controllers often keep decisions in effect for a 10 second period without revising them. Every control cycle, the controller computes an over-approximation stopDist(p,v,a_{b}) of the stopping distance, the distance that the train will travel before stopping if it were to accelerate during the current control cycle, but then brake continuously starting at the next control cycle, until it comes to a halt. If the distance left to the end of movement authority e exceeds stopDist(p,v,a_{b}), the controller continues free driving (with any acceleration or deceleration choice within the physical limits of the train), otherwise it brakes. This control cycle, α(stopDist), is parametric in stopping distance stopDist, and expressed aₛ a hybrid program in Model 1, shown in FIG. 2.

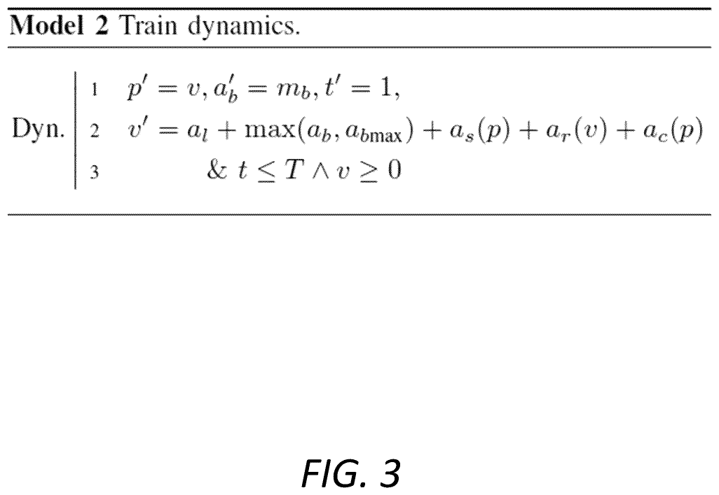

Train Dynamics-Model 2, shown in FIG. 3, describes the physical motion of the train according to the abstract mathematical model of Eq. (2) augmented with a clock t′=1 to switch back to control after at most time T. All constants are left as symbolic and safety is proven for all values, so that individual railroads have the flexibility to instantiate them with the values that apply to their system but inherit the safety results of the disclosed embodiments. This generality in controller design comes at the cost of higher proof complexity but compared to the alternative where these constants would be initialized with a conservative value, this allows for more efficient, tailored controllers adapted to the specific rail operation.

Stopping Distance—To decide between free driving and braking, the controller computes the upper bound stopDist(p,v,a_{b}) on the distance covered over one time period of acceleration and subsequently braking to a stop. Thus, the models provide two distinct specifications of the distance that the train will take to stop. The first, indirect specification is through the differential equation in Model 2 that implicitly describes the physical motion of the train. The second, approximate specification is stopDist in Line 2 of Model 1, an explicit arithmetic expression that the controller can evaluate efficiently to make decisions at runtime. Efficiency concerns demand that stopDist(p,v,a_{b}) be as tight as possible. If the bound is too large, the controller enforces braking unnecessarily. But verifiable safety requires stopDist(p,v,a_{b}) to provably be an upper bound on the distance that the train covers (as determined by the dynamic model). The tightest possible bound is the exact solution of the differential equation. However, even ignoring the effect of air brakes, the differential equation requires trigonometric solutions. Transcendental function arithmetic is undecidable. To ensure mathematical provability, polynomial approximations are developed, which is a delicate design task because automated decision procedures for polynomial real arithmetic validity are computationally expensive. This constrains the complexity of the polynomial approximations that can be used as upper bounds. A balance can be struck between conflicting concerns: striving for efficiency while satisfying mathematical provability.

To illustrate this approach, start with a simple conservative expression for stopDist. This expression is proved safe for the full model including slope, curve friction, air brake propagation, and aerodynamic drag. The approximation is then improved, focusing on one contributing factor at a time.

Conservative Stopping Distance-A conservative controller will now be constructed by instantiating control loop with an expression for stopDist and proving it safe. Referring back to the train dynamics in Eq. (2), an upper bound for v is first needed. Integrating this bound via p′=v computes a stopping distance upper bound.

The first impediment to obtaining a provable upper bound for v is that grade and curvature maps aₛ and a_{c} are arbitrary functions, constrained only by upper and lower bounds, and bounded gradients. At runtime, the train knows their exact values as the controller is instantiated with maps for the railroad it runs on. However, these maps are unknown at proof time. And yet, the proof has to show safety of the train control ahead of time for all possible track maps in order to justify safety of the train controller. To obtain a provable upper bound on stopping distance, the proof is therefore based on the limited information that we do have about the maps: upper bounds on the potential values of aₛ and a_{c}.

A naive upper bound on aₛ is the value of acceleration that the train experiences when it is on the steepest permissible downward slope, mₛ. The proof shows that the distance required to stop for any permissible grade map cannot exceed the distance computed with the steepest downward slope. It first shows that the true acceleration is bounded above by an acceleration that uses the highest permissible value of grade acceleration, then that actual velocity cannot exceed the velocity computed using the worst-case acceleration, and consequently, that traveled distance cannot exceed the stopping distance computed using the worst-case estimate of velocity.

Accounting for grade force is important. On a downward hill, for example, a train with a controller that ignores grade would roll forward even at the end of its movement authority which may cause accidents. In contrast, curve resistance can be safely ignored when approximating stopDist, because resistances shorten stopping distance (upper bound 0). These simplifications result in differential equation v′₂=aₗ+mₛ+aᵣ(v) because max(a_{b},a_{bmax})=0 while the train is accelerating, where v₂ is the upper bound on v that is integrated to compute stopDist. However, the solution v₂(t) is still transcendental:

$$( \sqrt{4 ( {a}_{l} + {m}_{s} ) {a}_{2} - {a}_{1}^{2}} ) \cdot \frac{tan ( t \frac{\sqrt{4 ( {a}_{l} + {m}_{S} ) {a}_{2} - {a}_{1}^{2}}}{2} + {tan}^{- 1} ( \frac{{a}_{1} + 2 {a}_{2} {v}_{0}}{\sqrt{4 ( {a}_{l} + {m}_{s} ) {a}_{2} - {a}_{1}^{2}}} ) ) - {a}_{1}}{2 {a}_{2}}$$

The culprits are the linear and quadratic terms in velocity from the Davis equation. With another simplification of 0 as an upper bound for aᵣ (resistance always works against the train's motion), a polynomial expression is derived for stopDist:

$${v}_{3}^{′} = {a}_{l} + {m}_{s} ⇒ {v}_{3} ( t ) = {v}_{0} + ( {a}_{l} + {m}_{s} ) \cdot t \qquad ( 3 )$$

$${p}_{3}^{′} = v ⇒ {p}_{3} ( t ) = {p}_{0} + ( {v}_{0} + \frac{{a}_{l} + {m}_{s}}{2} \cdot t ) \cdot t$$

where:
v₀ and p₀ are the initial values of speed and position.

The solutions provide a conservative stopping distance bound.

$${stopDist}_{b} ( p , v , {a}_{b} ) = v T + \frac{{a}_{max} + {m}_{s}}{2} \cdot {T}^{2} + \frac{{( v + ( {a}_{max} + {m}_{s} ) T )}^{2}}{2 ( {b}_{max} - {m}_{s} )} \qquad ( 4 )$$

Where the first and second terms represent the distance while accelerating and the third term represents the stopping distance from increased speed.

The conservative stopping distance stopDist; ignores its arguments p and a_{b}, but later refinements of stopDist functions also depend on p and a_{b}, which is why they are passed in.

The first two terms are the distance covered by the train in one control cycle of acceleration, while the third term is the distance that the train needs to stop should it start braking right after, assuming the worst-case value of 0 for da. This conservative distance is adjusted to account for grade force with its worst-case accelerating or decelerating effects. Substituting Eq. (4) into control cycle a results in the DDL hybrid program of the conservative controller: α(stopDist_{b}).

A physically important quantity is braking distance, the distance that the train will travel before coming to a stop should it start braking right now. an upper bound, brake Dist_{b}(v,a_{b}) is derived, which will be crucial to the proofs and the initial assumptions and is improved upon later.

$${brakeDist}_{b} ( v , {a}_{b} ) = \frac{{v}^{2}}{2 ( {b}_{max} - {m}_{s} )} \qquad ( 5 )$$

The last term of Eq. (4) is brakeDist_{b}(v₃(T),0) with v₃ according to Eq. (3) when

$${a}_{l} = {a}_{max} .$$

Initial assumptions init(brakeDist) parametrized by brakeDist, and initAirbrake (assumptions on air brakes) are required to prove the conservative controller safe. Assumptions about unspecified functions are represented by universal quantification over their input. This representation permits derivation of a formula about the unspecified function at any point of the train's evolution by substituting the quantified input with current values.

$$init ( brakeDist ) = {a}_{max} > 0 ∧ {b}_{max} > 0 ∧ {a}_{1} < 0 ∧ {a}_{2} < 0 ∧ e - p > brakeDist ( v , 0 ) ∧ {b}_{max} - {m}_{s} > 0 ∧ v \geq 0 ∧ {m}_{s} \geq 0 ∧ T > 0 ∧ ∀ x ( \vert {a}_{s} ( x ) \vert \leq {m}_{s} ) ∧ ∀ x ( {a}_{c} ( x ) \leq 0 ) \qquad ( 6 )$$

$$initAirBrake = {m}_{p} < 0 ∧ {a}_{b max} < 0 ∧ {m}_{b} = 0 ∧ {a}_{b} = 0$$

Theorem 1 is the DDL formula representing the safety of the conservative controller:

Theorem 1: The conservative braking controller guarantees that the train always remains within the end of the movement authority. The DDL formula below is provable, where a is the control loop from Model 1 parameterized with Eq. (4) for stopDist.

$$init ( {brakeDist}_{b} ) ∧ initAirBrake \to [ ( α ( {stopDist}_{b} ) ; Model 2 ) * ] e - p > 0$$

The proof has been done in the theorem prover KeYmaera X, but the central ideas are disclosed here. Loop invariant e−p≥brakeDist_{b}(v, 0)∧a_{b}≤0∧v≥0 is used and split into cases for free driving and braking corresponding to the nondeterministic choice in Lines 2-5 of Model 1. On braking, the invariant is maintained because the derivative of the distance that the train will take to come to a stop does not exceed the derivative of the distance to the end of movement authority (i.e., (stopDist_{b})′≤(e−p)′). On free driving for a control period T, the train maintains a distance to the end of movement authority of at least stopDist adjusted for time t since the last control decision:

$$v ( T - t ) + \frac{{a}_{max} + {m}_{s}}{2} {( T - t )}^{2} + \frac{{( v + ( {a}_{max} + {m}_{s} ) ( T - t ) )}^{2}}{2 ( {b}_{max} - {m}_{s} )}$$

by dC and dI. The required inequality relation between the derivatives:

$$- v \geq - v + {v}^{′} ( T - t ) - ( {a}_{max} + {m}_{s} ) ( T - t ) + \frac{( v + ( {a}_{max} + {m}_{s} ) ( T - t ) ) ( {v}^{′} - ( {a}_{max} + {m}_{s} ) )}{( {b}_{max} - {m}_{s} )}$$

holds because v′−(aₘₐₓ+mₛ)≤0.

### Safe Efficiency Improvements

To make our controller more efficient, the over-approximation for stopping distance must be improved. The FRA model presents two challenges common in embedded controllers: it uses functions whose exact values are unknown at proof time (slope and curve maps) and has many interacting forces. The disclosed techniques address these problems with two general principles: using quantified worst case bounds on unknown functions, and separation of dependencies. The first technique relies on the observation that the track changes are gradual and predictable (the rate of change of unknown functions is bounded). It drastically improves bounds on the effect of grade and curve over one time period of acceleration, after resolving circular dependencies between the variables of motion. The second technique improves the estimate brakeDist by accounting for air brake dynamics. It demonstrates a handling of triple integration, using mode-splitting to deal with the non-analytical change of behavior when brakes saturate. The third technique uses Taylor polynomials to capture the effect of resistance, which would otherwise lead to transcendental arithmetic.

Bound on Gradient—The train controller knows the current slope aₛ(p) and vertical curves of the track, which determine transitions from one track grade to another. This knowledge results in a bound hₘₐₓ on the difference in grade per unit length:

$$\vert \frac{\partial {a}_{s} ( x )}{\partial x} \leq {h}_{max} \vert ⇒ \vert {a}_{s}^{′} ( p ) \vert \leq {vh}_{max}$$

The second inequality follows from the first using the chain rule and p′=v. After time T, aₛ could have increased by no more than uhₘₐₓT, where u is some upper bound on v over the course of T time

Bound on Curve Resistance-Similar to bounding the gradient change, an upper bound on the rate of change of curve resistance can be computed aₛ a function of velocity using track geometry. Curve resistance depends on average curve curve(p). Assume that the tightest permissible curvature for the railroad corresponds to radius r. The greatest change in average curvature occurs when a train goes from a track with the greatest permissible curvature to a straight track (or vice versa). Over a small period of time dt, the portion of the train transitioning from greatest curvature to 0 curvature is dv, where v is velocity. So the rate of change of curve (p) (taken in radians) with respect to time is

$$- \frac{v}{lr}$$

where l is the length of the train. For a given train, a_{c} relates to curve with some constant multiplicative factor q. In this case, use

$${a}_{c}^{′} = q \frac{v}{lr} = {C}_{cft} v$$

with the constant factor

$${C}_{cft} = \frac{q}{lr} .$$

With this bound on the maximum rate of change of a_{c}, we now estimate the upper bound on curve resistance over time T, where p₀ is initial train position, to be:

$${a}_{c} ( {p}_{0} ) + u {C}_{cft} T$$

As before, u is an upper bound on velocity for duration T.

Tight Stopping Distance Approximation—The upper bounds āₛ on gradient and ā_{c} on curve resistance are summarized as:

$${a}_{s} ( p ) \leq {\overline{a}}_{s} ( {p}_{0} ) = min ( {m}_{s} , {a}_{s} ( {p}_{0} ) + u {h}_{max} T )$$

$${a}_{c} ( p ) \leq {\overline{a}}_{c} ( {p}_{0} ) = min ( 0 , {a}_{c} ( {p}_{0} ) + u {C}_{cft} T )$$

This enables improvement of the estimation of stopping distance:

$${v}_{4}^{′} = {a}_{l} + {\overline{a}}_{s} ( {p}_{0} ) + {\overline{a}}_{c} ( {p}_{0} ) ⇒ {v}_{4} ( t ) = {v}_{0} + ( {a}_{l} + {\overline{a}}_{s} ( {p}_{0} ) + {\overline{a}}_{c} ( {p}_{0} ) ) T \qquad ( 7 )$$

Upper bound v₄ is tighter than v₃ of Eq. (3) and thus integrates to an improved stopping distance estimate. It depends (transitively through āₛ and ā_{c}) on the unknown upper bound u on velocity, which is still needed to estimate provably correctly.

Circular Dependencies—The upper bound on velocity, u, is undefined in Eq, (7) above. The bound v₄ cannot be used for u, since v₄ itself is phrased in terms of u. The problem is a circular dependency between aₛ and v: the bound on slope acceleration aₛ depends on speed v, while the upper bound on speed v, in turn, depends on slope acceleration aₛ and likewise for a_{c}. Physically, this is because if the train is moving faster, less is known about the nature of the track (e.g., its curve and slope) after the passage of some time, as the train is farther from its previous position on the track. However, information about the grade curve is needed to better estimate the velocity at which the train is traveling. To cut through these circular dependencies, the conservative estimations of these quantities are used as a base case to bootstrap incrementally finer computations, as presented below.

The initial upper bounds mₛ for aₛ and 0 for a_{c} are used to get a conservative bound v(t)≥v₀+(aₘₐₓ+mₛ)t, so that u=v₀+(aₘₐₓ+mₛ)T. Because (aₘₐₓ+mₛ) is a positive upper bound on the train's acceleration, velocity could have increased no more than (aₘₐₓ+mₛ)T. Hence, u is indeed an upper bound on v through the T time interval. Substituting this u refines the gradient and curve resistance bounds.

$${\overline{a}}_{s} ( {p}_{0} ) = min ( {m}_{s} , {a}_{s} ( {p}_{0} ) + ( {v}_{0} + ( {a}_{max} + {m}_{s} ) T ) {h}_{max} T )$$

$${\overline{a}}_{c} ( {p}_{0} ) = min ( 0 , {a}_{c} ( {p}_{0} ) + ( {v}_{0} + ( {a}_{max} + {m}_{s} ) T ) {C}_{cft} T )$$

These expressions give the chosen definitions of āₛ and ā_{c} by replacing placeholder velocity bound u.

In principle, this upper bound could be further improved on speed by using v₄ to obtain an even better bound on aₛ and a_{c}, which could in turn yield an improved bound on v. However, extra levels of extrapolation increase proof cost and computation time when the controller is run. Each extra intermediate bound requires a constant number of extra steps in the proof, but provides diminishing efficiency gains in return. Intuitively, proof length is asymptotically linear in number of iterations because under optimal proof rule application ordering, each iteration induces one extra application of rule dC to introduce the intermediate bound into the proof tree, and rule dI to justify this intermediate bound.

The stopDist expression below uses 14 with u=v₀+ (aₘₐₓ+mₛ)T to estimate stopping distance, which is sufficiently tight to make useful control decisions.

$${stopDist}_{s} ( p , v , {a}_{b} ) = vT + ( \frac{{a}_{max} + {\overline{a}}_{s} ( p ) + {\overline{a}}_{c} ( p )}{2} ) {T}^{2} - \frac{{( v + ( {a}_{max} + {\overline{a}}_{s} ( p ) + {\overline{a}}_{c} ( p ) ) T )}^{2}}{2 ( {b}_{max} - {m}_{s} )} \qquad ( 8 )$$

Further initial assumptions are needed to prove the improved slope-exploiting controller α(stopDistₛ) safe. These assumptions represent the result of the track environment discussion used for the computer-checked proof.

$${init}_{s} ( brakeDist ) ≡ init ( brakeDist ) \qquad ( 9 )$$

$$⋀ {a}_{max} - {m}_{s} + {m}_{c} > 0 ⋀ {h}_{max} \geq 0 ⋀ {m}_{c} \leq 0 ⋀ {C}_{cft} \geq 0$$

$$⋀ ∀ x ( {a}_{c} ( x ) \geq {m}_{c} ) ⋀ ∀ {x}^{′} ∀ x ( \vert {a}_{c}^{′} \vert \leq {x}^{′} {C}_{cft} ) ⋀ ∀ {x}^{′} ∀ x ( \vert {a}_{s}^{′} \vert \leq {x}^{′} {h}_{max} )$$

This technique applies to time-triggered controllers (where a control loop runs with some known maximum latency and sensors measure current state every cycle) for physical systems with functions affecting the environment that are unknown except for bounds on their rate of change. The future value of the functions can be bounded in terms of their worst-case rate of change. Furthermore, these bounds can be used to compute bounds on other variables in the system, just as here a bound on velocity was used to bound slope and curve effect, which was again used to obtain a better bound on velocity. The situation arises frequently in practice: examples of unknown functions are a potential field, or a noise or error effect, which may have circular dependence with position.

Theorem 2: The slope-estimating controller guarantees that the train stays within its movement authority. The DDL formula below is provable, where a is the control loop from Model 1 parameterized with Eq. (8) for stopDist.

$${init}_{s} ( {brakeDist}_{b} ) ⋀ initAirBrake \to [ {( α ( {stopDist}_{s} ) ; Model 2 )}^{*} ] e - p > 0$$

The proof (by proof in KeYmaera X) builds on the ideas from Theorem 1. The loop rule is applied with the same loop invariant as Theorem 1. If the train brakes, differential invariant rule dI again shows that the loop invariant holds throughout differential equation evolution.

If the train chooses to accelerate, then as before, the train maintains at least a distance of stopDistₛ adjusted for time t since the last control decision. Unlike before, āₛ instead of mₛ accounts for worst-case aₛ, and ā_{c} instead of 0 accounts for worst-case a_{c}. Again, dI proves that this adjusted inequality remains true. To prove the required inequality on the derivatives, differential cut rule dC is used to show āₛ(p₀)≥aₛ(p) throughout the control cycle, and ā_{c}(p₀)≥a_{c}(p). There are two branches for each cut corresponding to how the min in āₛ and c resolve. For example, using initial position and velocity v₀ and p₀, for āₛ, it is necessary to show that aₛ(p)≤mₛ, and aₛ(p)≤aₛ(p₀)+uhₘₐₓT. While the former follows from the quantified assumption on aₛ(p), to prove the latter, elapsed time is adjusted for t, to argue that aₛ(p)≤aₛ(p₀)+(v₀+uhₘₐₓ(T−t)), proved using dI. The required derivative inequality follows from instantiating the quantified assumption bounding the rate of change of (aₛ(p))′≤uhₘₐₓ with the current position and showing that u is an upper bound on v in the control loop. The argument for a_{c} is analogous.

Effect of Air Pressure Brakes—The term brakeDist; conservatively neglects the significant effects of air brakes to avoid reasoning about their time dependence. A tighter brakeDistₐ that accounts completely for air brakes will now be derived. It specifies a controller that simultaneously benefits from the slope and curve estimation previously discussed, and from air brake dynamics. The central insight required to prove the improved controller safe is how to compose reasoning about time-dependent air brake propagation and velocity-dependent slope and curve estimations. The component of stopDist affected by air brakes, brakeDistₐ is first shown to be the desired upper bound on distance to brake throughout the control loop. Then, holding brakeDistₐ constant, the differential reasoning on slope and curve estimation previously described is performed. The two results together permit an overall proof of safety of the air brake-exploiting controller.

To derive the improved brakeDistₐ, some intermediate functions from air brake dynamics are first computed. In Eq. (2), during brake ramp-up, with slope relaxed pessimistically to mₛ, and curve and resistance to 0, max(a_{b},a_{bmax}) evaluates to a_{b}, and mₚ to mₚ. The solution for v in the resulting differential equation v′=bₘₐₓ−mₛ+a_{b},a′_{b}=mₚ is quadratic in t:

$$v = {v}_{0} - ( {b}_{max} - {m}_{s} + {a}_{b} ) t + \frac{1}{2} {m}_{p} {t}^{2} \qquad ( 10 )$$

Function t_{b} in Eq. (11) computes the time the train takes to achieve full braking by subtracting current brake buildup a_{b} from maximal air braking a_{bmax}, and dividing by the rate of increase in air brake force mₚ. If the train comes to a stop before air brake saturation, it instead evaluates to the time until the train stops, as computed by solving Eq. (10) for v=0.

$${t}_{b} ( v , {a}_{b} ) = min ( ( {a}_{b max} - {a}_{b} ) / {m}_{p} , \frac{( {b}_{max} - {m}_{s} + {a}_{b} ) - \vert {( {b}_{max} - {m}_{s} + {a}_{b} )}^{2} - 2 {m}_{p} v \vert}{{m}_{p}} ) \qquad ( 11 )$$

The distance that the train travels before either stopping or reaching maximum air brake effect is:

$${\int }_{0}^{{t}_{b} ( v , {a}_{b} )} p dt = {vt}_{b} ( v , {a}_{b} ) + \frac{1}{2} ( {b}_{max} - {m}_{s} + {a}_{b} ) {{t}_{b} ( v , {a}_{b} )}^{2} + \frac{1}{6} ( {m}_{p} ) {{t}_{b} ( v , {a}_{b} )}^{3}$$

The velocity of the train after this period of buildup, by Eq. (10), is:

$${v}_{f} = v - ( {b}_{max} - {m}_{s} + {a}_{b} ) {t}_{b} ( v , {a}_{b} ) + \frac{1}{2} {m}_{p} {{t}_{b} ( v , {a}_{b} )}^{2}$$

So, after the brakes finished ramping up, the distance traveled until the train comes to a halt is:

$$\frac{{v}_{f}^{2}}{2 ( {b}_{max} - {m}_{s} - {a}_{b} )}$$

using Newton's third equation of motion. If the train stops before finishing brake ramp-up, v_{f} evaluates to 0, aₛ required. Adding the upper bounds on distance traveled before and after brake ramp-up results in brakeDistₐ(v,a_{b}) in Eq. (12) below, an upper bound on braking distance that accounts for the effect of air brakes. While this derivation for controller design is manual, its result will be verified by computer-checked proof in Theorem 3 below.

$${brakeDist}_{a} ( v , {a}_{b} ) = {vt}_{b} ( v , {a}_{b} ) - \frac{1}{2} ( {b}_{max} - {m}_{s} + {a}_{b} ) {{t}_{b} ( v , {a}_{b} )}^{2} + \frac{1}{6} ( {m}_{p} ) {{t}_{b} ( v , {a}_{b} )}^{3} + \frac{{( v - ( {b}_{max} - {m}_{s} + {a}_{b} ) {t}_{b} ( v , {a}_{b} ) + \frac{1}{2} {m}_{p} {{t}_{b} ( v , {a}_{b} )}^{2} )}^{2}}{2 ( {b}_{max} - {m}_{s} - {a}_{b max} )} \qquad ( 12 )$$

$${stopDist}_{a} ( p , v , {a}_{b} ) = vT + ( \frac{{a}_{max} + {\overline{a}}_{s} ( p ) + {\overline{a}}_{c} ( p )}{2} ) {T}^{2} + {brakeDist}_{a} ( v + ( {a}_{max} + {\overline{a}}_{s} ( p ) + {\overline{a}}_{c} ( p ) ) T , 0 )$$

To prove the invariant that after a control cycle of braking, e−p>brakeDistₐ(v,aₐ), three dynamically distinct cases must be considered: (i) when max(a_{b},a_{bmax}) is a_{bmax}; (ii) when it is a_{b}, and t_{b}(v,a_{b}) evaluates to (a_{bmax}−a_{b})/mₚ; and (iii) when it is a_{b} but t_{b}(v,a_{b}) evaluates to

$$\frac{( {b}_{max} - {m}_{s} + {a}_{b} ) - \vert {( {b}_{max} - {m}_{s} + {a}_{b} )}^{2} - 2 {m}_{p} v \vert}{{m}_{p}} .$$

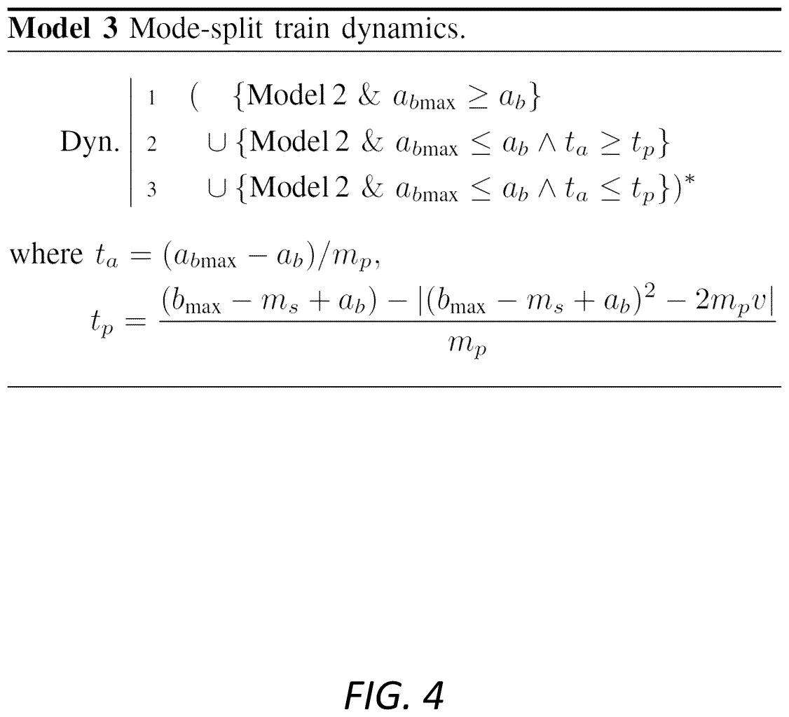

The model dynamics are split into these three evolution domains, branching between the three possibilities in a loop to transition between modes freely (Model 3, shown in FIG. 4). This does not affect the semantics of evolution: per train dynamics, mode transition happens at most once (from (ii) to (i) or (ii) to (iii)). Unrolling the loop to two iterations, one per mode, suffices to model train behavior. This split formulation simplifies syntactic proofs.

Theorem 3: The air-brake-exploiting controller guarantees that the train stays within its movement authority. The DDL formula below is provable, where α is the control loop from Model 1 parameterized with Eq. (12) for stopDist.

initₛ(brakeDistₐ)∧initAirBrake→[(α(stopDistₐ);Model 3)*]e−p>0

The high level idea of the proof (in KeYmaera X) is to use an outer loop invariant e−p≥brakeDist(v,aₐ)∧a_{b}≤0∧v≥0 and again split into free driving and braking cases. On braking, the outer loop invariant is maintained in each of the three dynamics modes using an inner loop invariant consisting of 4 formulas, the most important of which is e−p>brakeDist(v, max(a_{b},a_{bmax})).

On free driving:

$$b r a k e D i s {t}_{a 0} = b r e a k D i s {t}_{a} ( ( v + ( {a}_{max} + {\overline{a}}_{s} ( p ) + {\overline{a}}_{c} ( p ) ) ) T , 0 )$$

is truly an upper bound on all reachable brake Dist (v, max(a_{b},a_{bmax})) values in the control cycle. Then, holding brakeDistₐ₀ constant, a proof similar to that for Theorem 2 is followed to show that, in every mode, the increase in p does not exceed the decrease in distance buffer

$$vT + ( \frac{{a}_{max} + {\overline{a}}_{s ( p )} + {\overline{a}}_{c} ( p )}{2} ) {T}^{2}$$

The free driving inner loop invariant consists of 14 formulas, most of which state that various upper bound expressions (such aₛ on velocity, grade and curve) remain upper bounds over the course of the loop. By monotonicity, then, e−p>distance buffer+brakeDistₐ₀>brakeDist(v,max(a_{b},a_{bmax})).

Exploiting Resistance-Exactly accounting for the quadratic dependence of resistance on velocity, as discussed above, leads to an undecidable, transcendental exact solution for stopping distance. The controller must instead use an approximation. Because polynomial arithmetic is decidable, Taylor polynomials are a natural way to obtain decidable approximations. The disclosed embodiments apply Taylor approximations to the FRA model, identifying techniques generalizable to verified control for other embedded systems with transcendental dynamics.

The Davis equation implies

$${v}^{′} \geq ( {a}_{max} + {\overline{a}}_{s ( p )} + {\overline{a}}_{c} ( p ) ) + {a}_{1} v + {a}_{2} {v}^{2}$$

The first-order Taylor polynomial of this expression for velocity is

$${v}_{0} + ( ( {a}_{max} + {\overline{a}}_{s ( p )} + {\overline{a}}_{c} ( p ) ) + {a}_{1} {v}_{0} + {a}_{2} {v}_{2}^{2} ) t$$

Using this approximation at time T, with aₗ=aₘₐₓ, as an upper bound for velocity after a time period of acceleration, Eq. (13) is computed for stopping distance that leverages resistance. While this derivation is manual, its result will be verified by computer-checked proof in Theorem 4 below.

$${\overline{v}}^{′} = ( {a}_{max} + {\overline{a}}_{s} ( p ) + {\overline{a}}_{c} ( p ) ) + {a}_{1} v + {a}_{2} {v}^{2} \qquad ( 13 )$$

$${stopDist}_{t} ( v ) = vT + ( \frac{{a}_{max} + {\overline{a}}_{s ( p )} + {\overline{a}}_{c} ( p )}{2} ) {T}^{2} + b r a k e D i s {t}_{a} ( v + ( {\overline{v}}^{′} ) T , 0 )$$

Unlike previous stopping distance estimates, this expression is not always an upper bound. It uses resistance for the original velocity v₀, which is only a conservative bound when resistance is low enough to permit acceleration. This condition is captured by predicate vbound in Eq. (14):

$$vbound ( v ) ≡ ( {a}_{max} + {\overline{a}}_{s ( p )} + {\overline{a}}_{c} ( p ) ) + {a}_{1} v + {a}_{2} {v}^{2} \geq 0 \qquad ( 14 )$$

For the Taylor approximation controller (Model 4), the stopDistₜₚ predicate is defined in Eq. (15), which, unlike previous expressions for stopping distance, returns a truth value. It uses previous definitions stopDist, from Eq. (13), vbound. From Eq. (14) to determine when stopDist, is applicable, and stopDist_{b} from Eq. (8) is used as a fallback.

$${stopDist}_{tp} ( p , v , {a}_{b} ) ≡ e - p > {stopDist}_{s} ( p , v , {a}_{b} ) ∨ ( vbound ( v ) ∧ e - p > {stopDist}_{t} ( v ) ) \qquad ( 15 )$$

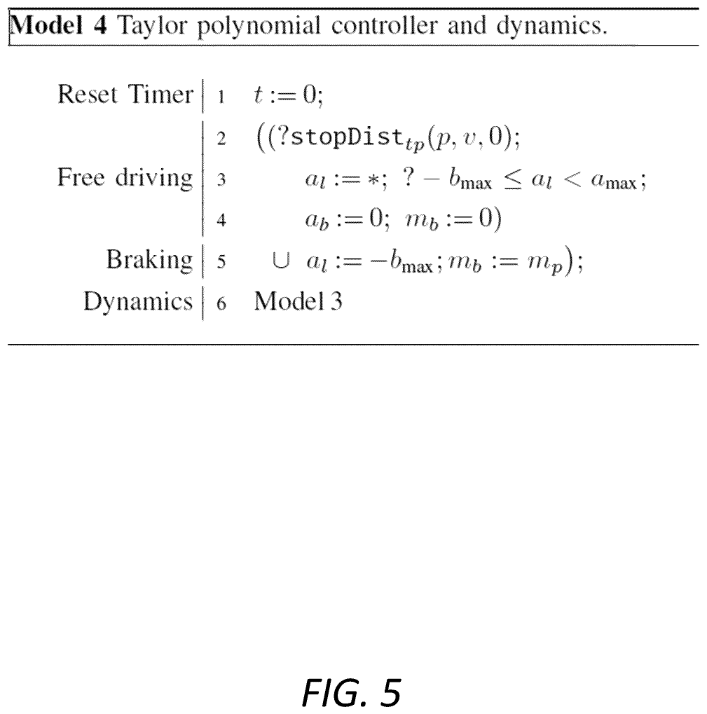

Higher order Taylor polynomials permit analogous reasoning. Theorem 4 expresses that the Taylor polynomial controller in Model 4, shown in FIG. 5, is safe.

Theorem 4: The Taylor polynomial controller guarantees that the train stays within its movement authority. The DDL formula below is provable:

$${init}_{s} ( b r a k e D i s {t}_{a} ) ∧ initAirBrake \to [ ( Model 4 ) * ] e - p > 0$$

The proof (in KeYmaera X) starts by showing that the loop invariant from Theorem 3 is maintained (using DDL rule loop). The case where the train is braking proceeds similar to Theorem 3. When the train is accelerating, a showing that the controller has insisted on a sufficient distance margin (stopping distance), so that even after a time period, the train has enough space to stop, is necessary. As the Taylor polynomial computes the stopping distance, it must be proven that it actually is an upper bound. A monotonicity argument is used by introducing an auxiliary variable that represents a “ghost” train, perpetually traveling down worst possible slope āₛ and curve ā_{c}. This isolates slope and curve from the effect of resistance, breaking interdependence. The Taylor polynomial result, derived on the ghost train, shows that it goes no slower than the real train, and that consequently the Taylor polynomial result must hold for the real train. Other elements of the proof remain similar to Theorem 1.

### Kinematic Train Model Proofs

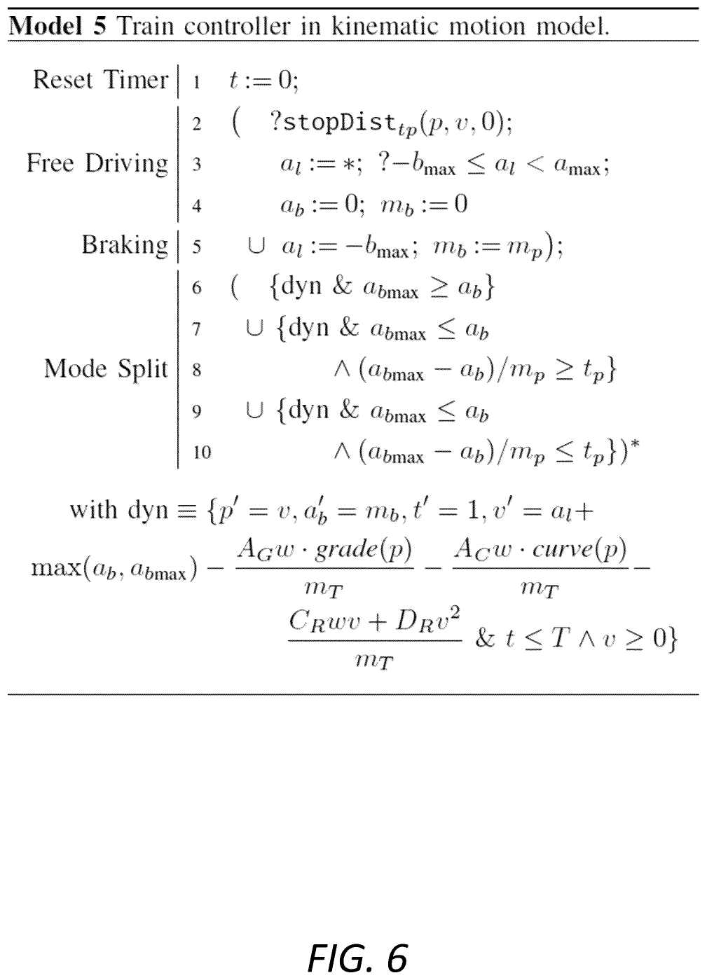

A proof for the FRA model derives from the proof for the abstract mathematical models (e.g., Theorem 4), by uniform substitution, which replaces abstract function symbols with specific terms using the correspondence previously discussed. Model 5, shown in FIG. 6, lists the model resulting from substitution.

A corollary posits that the kinematic train model is safe. That is, the train controller for the FRA model never overshoots the end of movement authority. The following formula is provable with

$${b}_{max} = \text{} \frac{{F}_{B}}{{m}_{T}} + \frac{{A}_{R} w + {B}_{R} n}{{m}_{T}} and {a}_{max} = \frac{{F}_{L}}{{m}_{T}} + \frac{{A}_{R} w + {B}_{R} n}{{m}_{T}} : {init}_{s} ( b r a k e D i s {t}_{a} ) ∧ initAirBrake \to [ ( Model 5 ) * ] e - p > 0$$

Here is the proof. By uniform substitution from Theorem 4, using the substitutions σ below:

$$σ \{ \begin{matrix}{a}_{max} ↦ \frac{{F}_{L}}{{m}_{T}} - \frac{{A}_{R} w + {B}_{R} n}{{m}_{T}} \\ {a}_{s} ( p ) ↦ - \frac{{A}_{G} w \cdot grade ( p )}{{m}_{T}} \\ {a}_{r} ( v ) ↦ - \frac{{C}_{R} w v + {D}_{R} {v}^{2}}{{m}_{T}} \\ {b}_{max} ↦ \frac{{F}_{B}}{{m}_{T}} + \frac{{A}_{R} w + {B}_{R} n}{{m}_{T}} \\ {a}_{c} ( p ) ↦ - \frac{{A}_{c} w \cdot curve ( p )}{{m}_{T}}\end{matrix}$$

### Evaluation

For validation, ModelPlex can be used to derive a controller monitor from Model 5 that measures the safety margin in decisions of previous brake enforcement controllers and the verified control presented herein. That way, measurements of if, and how well, the verified train controllers and existing controllers agree can be used to assess the safety of those existing systems and the efficiency of the model. Existing brake enforcement controllers brake to a full stop once engaged.

The ModelPlex monitor computes a robustness measure indicating how close a decision is to losing the safety proof. When the robustness measure is positive, the decision is guaranteed to remain provably safe so that the system enjoys the safety proof of the verified model. When it is negative, emergency brakes should be applied for safety reasons. The ModelPlex controller monitor follows the structure of the verified model when it computes robustness. For example, a monitor for Lines 2-3 of Model 5 describes their effect with the formula stopDistₜₚ(p,v,0)∧−bₘₐₓ≤aᵢ<aₘₐₓ which translates to the robustness measure.

$$min ( max ( min ( e - p - stopDis {t}_{t} ( v ) , ( {a}_{max} + {\overline{a}}_{s} ( p ) + {\overline{a}}_{c} ( p ) ) + {a}_{1} v + {a}_{2} {v}^{2} ) ,$$

$$e - p - {stopDist}_{a} ( p , v , 0 ) ) , {a}_{l} + {b}_{max} , {a}_{max} - {a}_{l} ) .$$

The most important elements of the full Model 5 monitor are: (1) in free driving (when stopDistₜₚ is satisfied) it combines remaining position margin, that is, the larger of Taylor margin e−p−stopDistₜ when vbound (v), or fallback margin e−p−stopDistₐ with acceleration choice robustness min (aₗ+bₘₐₓ,aₘₐₓ−aₗ) from control decision a:=*;?−bₘₐₓ≤1<aₘₐₓ. and speed robustness. That is, v from evolution domain . . . &v≥0; and (2) during braking, which is always allowed, it measures speed robustness, that is, v per evolution domain constraint.

Because the robustness measure of ModelPlex combines multiple quantities of incompatible units, there is no direct interpretation of its magnitude, but only of its sign. For validation, the train model of Eq. (2) was implemented in Python by numerical integration, instantiating the model parameters per the FRA model. These parameter values are estimated from train test runs and standards and require careful consideration of their units.

The evaluation compares start braking and stopping points of trains, highlighting braking performance in terms of overshoot (safety risk) and undershoot (performance objective of a maximum undershoot of 1000 ft) of the end of movement authority. The baseline controllers were implemented using numeric forward Euler integration to simulate the model to determine the stopping distance. The verified controllers neither use numeric integration nor include the dynamic model, but instead decide based on the stopping distance over-approximation stopDistₜₚ from Eq. (15).

The most interesting train behavior arises from the subtle interplay between air pressure propagation, aerodynamic/roll resistance, and acceleration/deceleration due to slope. It peaks on crests that change gradient from uphill to downhill and in troughs that change gradient from downhill to uphill. When calculating stopping distance, numerical integration in the baseline enforcement algorithms discretizes train speed and position to calculate forces, which overestimates resistance while simultaneously underestimating available brake force. Acceleration/deceleration due to slope is even more subtle as it depends on the position of the train along the slope (e.g., on a crest changing from uphill to downhill, deceleration on the uphill segment is overestimated until the train passes the top, afterwards acceleration is underestimated). These effects do not balance out and thus make numerical integration errors unreliable and hard to predict. Moreover, changing the integration step size shifts how distance estimates are biased towards undershoot or overshoot (e.g., in typical configurations, brake ramp-up is the dominating influence on stopping distance, and so larger integration step sizes bias towards undershoot). As a result, for any given configuration of numerical integration in enforcement algorithms, scenarios can be constructed where the numerical integration underestimates stopping distance and train enforcement exhibits unsafe behavior. The formal models and proofs presented herein design provably correct stopping distance over-approximations instead of using numerical integration and are, therefore, not subject to these intricate safety tradeoffs.

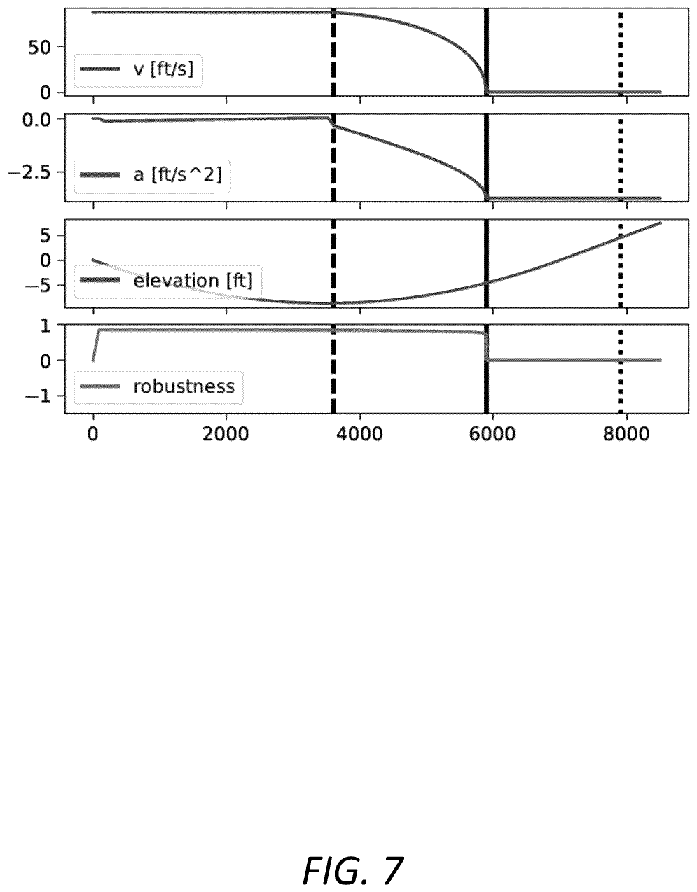

Stopping Behavior in Troughs—The first validation in FIGS. 7-9 shows a train configuration of a medium (75 cars), loaded (car weight 286 klbf), mixed freight train traveling at an initial speed of 60 mph in a trough, with train starting position at Oft. The trough is configured with uniform rate of change from 0.5% downhill to −0.5% uphill between positions Oft and 7000 ft. Locomotive tractive effort and locomotive braking compensates for speed loss and gain due to gradient. Air brakes engage only for the full braking maneuver when attempting to not exceed the movement authority. The monitors and controllers are configured to match the trough maximum uphill/downhill gradient of 0.5% for slope estimation. A sweep of movement authority endpoints in the range 4000 ft-8000 ft with 10 ft steps identifies challenging configurations. The base enforcement algorithm underestimates stopping distance for 19 (of the 400) endpoints.

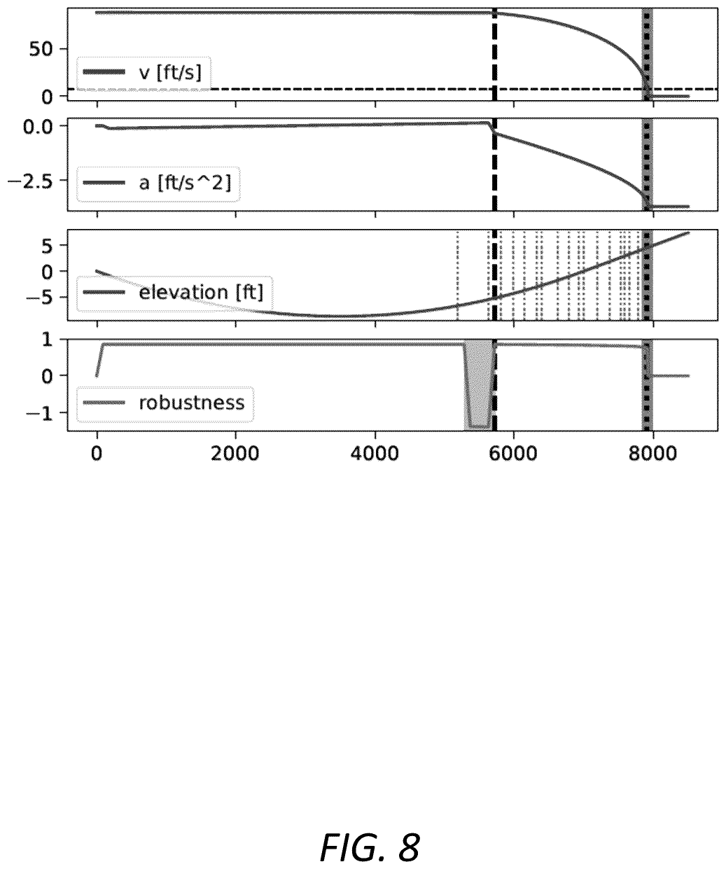

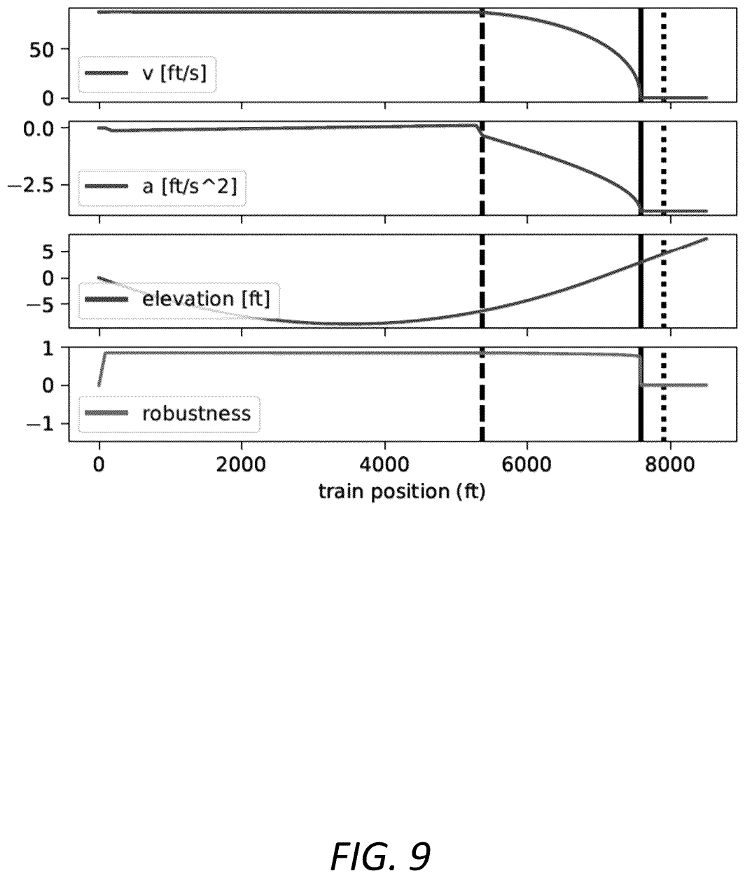

The base enforcement algorithm in FIG. 7 uses numeric integration to determine the stopping distance and adds a generous constant safety factor plus speed-dependent safety offset resulting in the train initiating braking at 3609 ft. The maneuver finishes at 5889 ft, stopping 2021 ft short of the end of movement authority. In FIG. 8, the verified controller does not use any such offsets. It initiates braking much later at position 5368 ft and stops at 7578 ft, which is significantly closer to the movement authority endpoint, limiting undershoot to 332 ft. The results shown in FIG. 8 removes the safety offset from the base enforcement algorithm in an experiment illustrating the subtle interplay between forces and their safety consequences. Even though the uphill segment of the trough helps reduce stopping distance, numeric integration overestimates this effect and initiates braking too late, which the monitor detects at 5368 ft. Should the train ignore the warning, it overshoots by 9 ft (highlighted in red) with a remaining speed of 7.8 fps when passing the desired stopping point. Initiating fallback control aₗ=−bₘₐₓ at the monitor violation would have kept the train from overshooting the movement authority. FIG. 9 shows that the verified controller (Model 5) limits the undershoot to 332 ft.

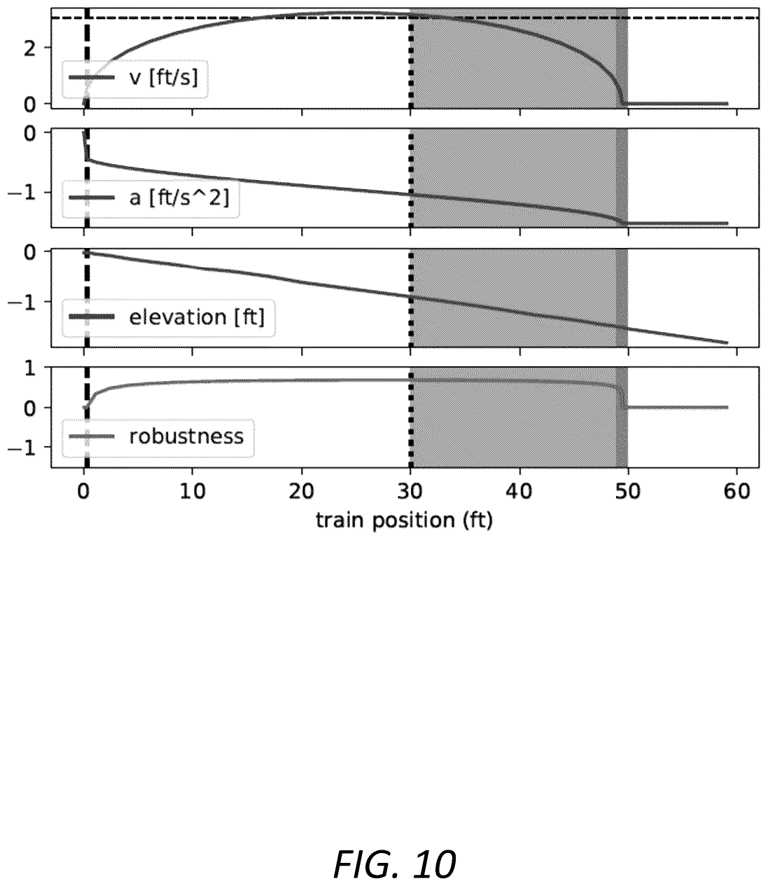

Stopping Behavior on Crests—An assumption in the brake enforcement algorithms and thus an initial condition in the proof is that train locomotives are not underpowered: their tractive effort is enough to overcome maximum uphill slope and stay stopped on the maximum downhill slope. FIG. 10 illustrates how an underpowered, initially stopped train starts rolling downhill until the air brakes build enough deceleration to stop the train. This configuration, violating initial conditions, is unsafe to start in the first place.

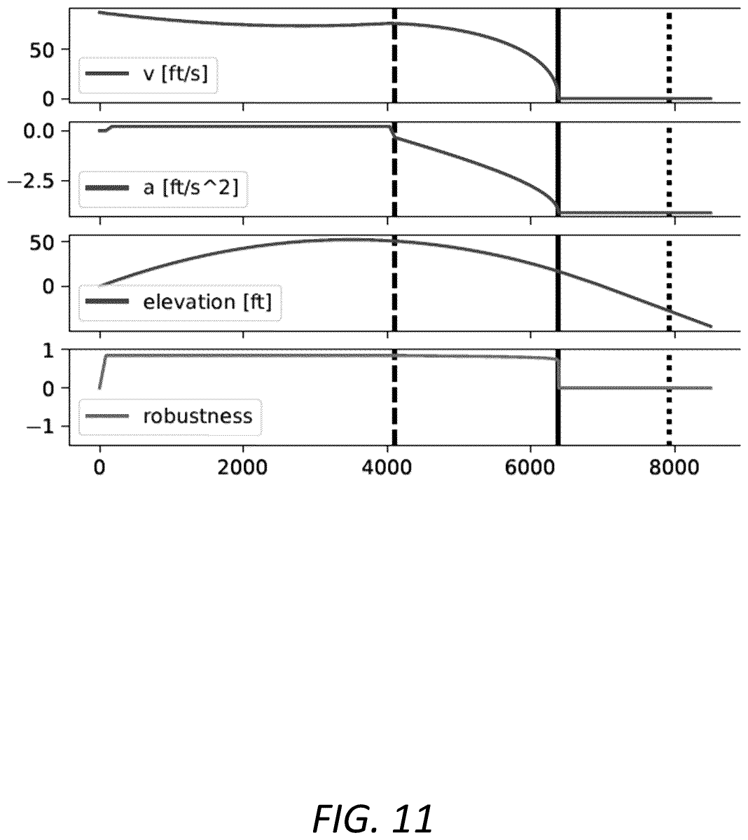

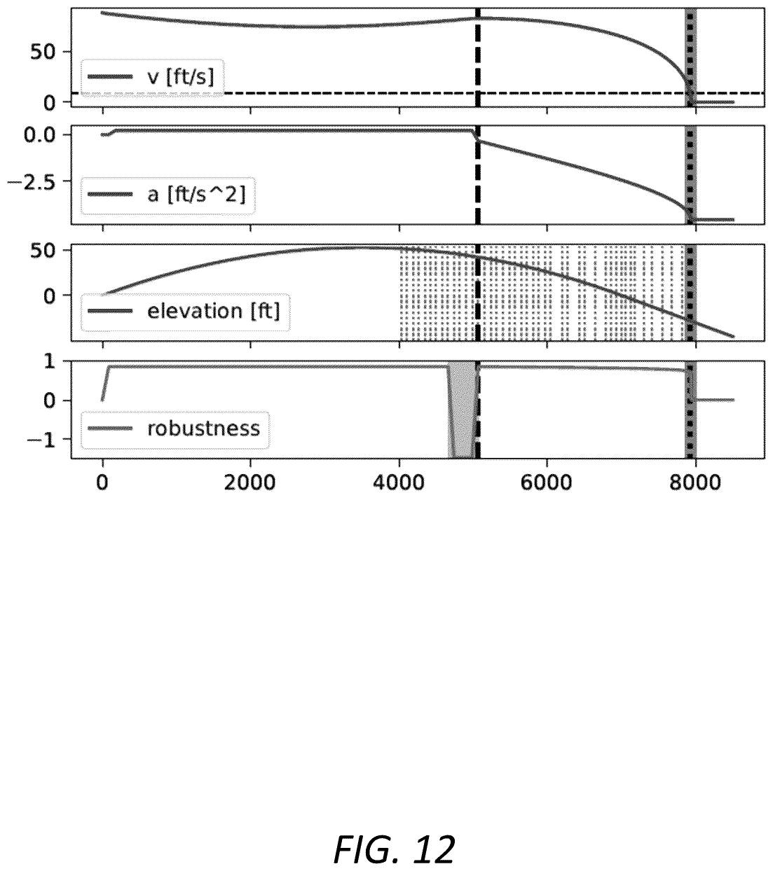

Underpowered locomotives are especially challenging on a crest where (full) tractive effort is needed to limit the speed loss on the uphill slope and regain desired speed on the downhill segment, but air brakes are needed to stay stopped. FIGS. 11-14 compares the behavior of the base enforcement algorithms and the verified algorithm with underpowered locomotives on a crest with movement authority endpoint at 7920 ft. In this experiment, the monitors and controllers are configured for a maximum uphill/downhill gradient of 3% for slope estimation.

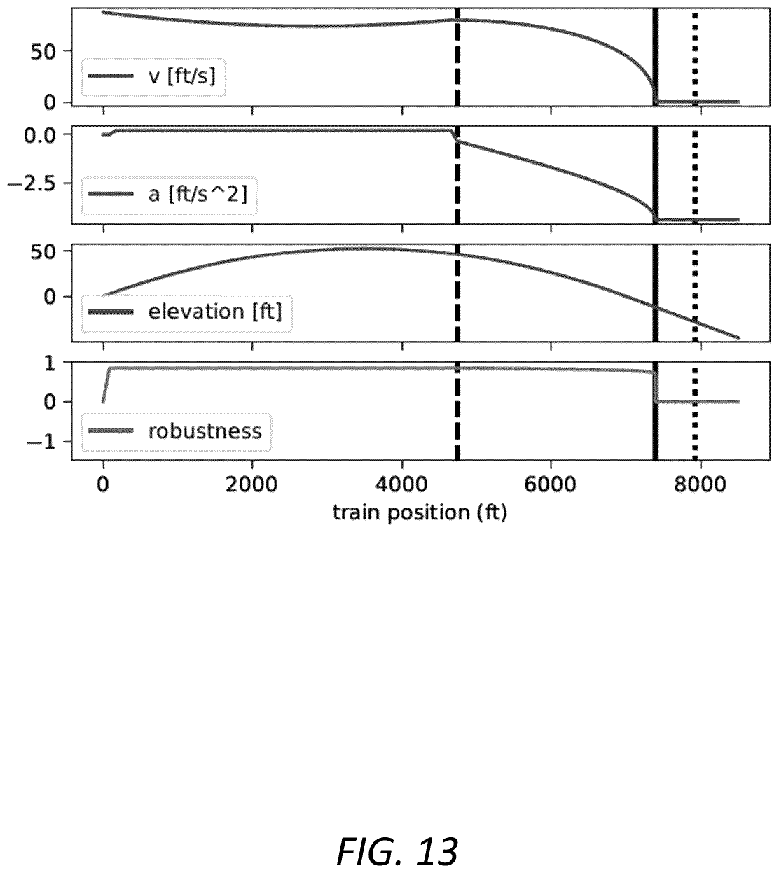

Numeric integration underestimates stopping distance in several configurations, whereas our verified controller correctly identifies the need to engage air brakes in time while simultaneously avoiding the inefficiencies of fudge factors. FIG. 11 shows the base enforcement algorithm results in a 1538 ft undershoot. FIG. 12 shows that the base enforcement algorithm with offset overshoots by 14 ft. The Light-gray dotted lines mark other movement authority endpoints in the range 4000 ft-8000 ft that the algorithm would also overshoot. FIG. 13 shows that the verified controller (Model 5) limits the undershoot to 528 ft.

Verified train controllers that account for the FRA model were formally verified with all its competing influences of track grade, curve resistance, air brakes and Davis resistance. Techniques that generalize to resolve challenges in safety critical embedded software design improved controller efficiency. Validation in simulation shows significant improvement in undershoot over conservative controllers that use safety offsets, and improved safety compared to controllers without safety offsets.

The invention has been described in the context of specific embodiments, which are intended only as exemplars of the invention. As would be realized, many variations of the described embodiments are possible. For example, variations in the design, shape, size, location, function and operation of various components, including both software and hardware components, would still be considered to be within the scope of the invention, which is defined by the following claims.

1. A method of designing and verifying safety of a train controller comprising:
creating a train dynamics model based on a mathematical abstraction of a kinematic model of a train;
proving the mathematical abstraction;
creating the train controller based on the mathematical abstraction;
proving the safety of the train controller with respect to the train dynamics model.

2. The method of claim 1 wherein the train controller and train dynamic model are expressed in differential dynamic logic.

3. The method of claim 2 wherein the train controller comprises a time control loop wherein, during every cycle, the controller computes a stopping distance of the train.

4. The method of claim 3 wherein the stopping distance comprises a distance travelled by the train before stopping if accelerated during the current cycle and then continuously braking during the next loop.

5. The method of claim 4 wherein the safety of the train controller is proven if a position of the train never exceeds an end of movement authority.

6. The method of claim 5 wherein a stopping distance of the train is expressed as a polynomial.

7. The method of claim 1 further comprising:
instantiating the proven train dynamics model.

8. The method of claim 7 wherein the instantiating comprises:
substituting abstract function symbols in the mathematical abstraction of the kinematic model with physical terms from a specific kinematic model of a train.

9. The method of claim 8 wherein the kinematic model is a high-fidelity physics model describing kinematic motion of the train along a track.

10. The method of claim 9 wherein the specific kinematic model is the Federal Railroad Administration freight train kinematic model.

11. The method of claim 1 wherein the mathematical abstraction of the kinematic model of the train is expressed as an ordinary differential equation in time comprising a plurality of variables selected from a group consisting of: train position, train velocity, position independent component of acceleration, acceleration due to use of air brakes, rate of change of air brake acceleration; acceleration due to grade; acceleration due to curvature and velocity-dependent resistance.

12. The method of claim 11 wherein acceleration due to grade and curvature are represented by unspecified, bounded functions mapping a position of the train to a numeric value for acceleration due to grade and average curvature.

13. The method of claim 1 wherein proof of the safety of the train controller is expressed in differential dynamic logic.

14. The method of claim 5 wherein efficiency of the train controller is maximized when undershoot of the end of movement authority is minimized.

15. The method of claim 14 wherein the train controller minimizes the undershoot by incorporating the effects of track gradient and curve resistance in the calculation of stopping distance.

16. The method of claim 15 wherein the train controller further minimizes the undershoot by incorporating the effects of air brakes in the calculation of stopping distance.

17. The method of claim 15 wherein the mathematical abstraction of a kinematic model of a train comprises multiple modes based on the effects of the air brakes.

18. The method of claim 17 wherein the cycles of the train controller are periodically triggered and further wherein each cycle comprises two iterations to account for transitions of the train from one mode to another.

19. The method of claim 8 further comprising:
monitoring the train controller for safe operation of the instantiated train dynamics model.

20. The method of claim 19 wherein monitoring further comprises:
computing a robustness measure indicating the proximity of decisions made by the train controller to loss of safety.

21. The method of claim 19 wherein the monitor is implemented using ModelPlex.

22. The method of claim 1 wherein the train controller, when verified for safety, is used to validate simulated and actual train runs.
